(19) United States
(12) Patent Application Publication
(10) Pub. No.: US 2011/0053381 A1
(43) Pub. Date: Mar. 3, 2011

(54) METHOD FOR MODIFYING INSULATING FILM WITH PLASMA

(75) Inventors: Takashi KOBAYASHI, Amagasaki-shi (JP); Daisuke KATAYAMA, Amagasaki-shi (JP); Yoshihiro SATO, Amagasaki-shi (JP); Junji HORII, Amagasaki-shi (JP); Yoshihiro HIROTA, Amagasaki-shi (JP)

(73) Assignee: TOKYO ELECTRON LIMITED, Tokyo (JP)

(21) Appl. No.: 12/866,145

(22) Filed: Aug. 4, 2010

Related U.S. Application Data
(63) Continuation-in-part of application No. PCT/JP2009/052442, filed on Feb. 6, 2009.

(30) Foreign Application Priority Data
Feb. 8, 2008 (JP) 2008-029478

(51) Int. Cl. H01L 21/465

(52) U.S. Cl. 438/726; 156/345.27; 257/E21.485

(57) ABSTRACT

Disclosed is a method for modifying an insulating film with plasma using a plasma processing apparatus which introduces a microwave into a processing chamber through a plane antenna having a plurality of holes. Processing gas containing a noble gas and oxygen is introduced into the processing chamber and microwave is introduced into the processing chamber through the plane antenna. Plasma composed mainly of O₂⁺ ions and O(¹D₂) radicals is generated in a pressure condition within a range of 6.7 Pa to 267 Pa to modify the insulating film with the plasma.

### TECHNICAL FIELD

The present invention relates to a method for modifying an insulating film formed with a method such as Chemical Vapor Deposition (CVD) by applying plasma.

### BACKGROUND ART

CVD method has been used widely to form insulating films such as a silicon oxide film in the process of manufacturing a variety of semiconductor devices. In CVD method, the insulating film is formed on an object to be processed by generating a vapor phase reaction on a raw material with a thermal energy or the like. However, numerous dangling bonds exist, and impurities or moistures originated from the raw material are included in the silicon oxide film formed with CVD method. On that account, the quality of the silicon oxide films need to be improved by an annealing treatment of higher than 900° C. after forming the films.

Since a recombination of Si—O bond is impossible in a heat energy supply, it is difficult to improve a film quality by an annealing treatment after the film is formed. Although a high temperature annealing treatment is necessary in order to increase a modification effect, the high temperature annealing tends to increase the amount of thermal treatment. If the amount of thermal treatment increases, a silicon substrate itself and a film formed thereon tend to be deformed and make it difficult to control the distribution of impurities diffused in a silicon layer. Thus, there is a concern that the quality and reliability of semiconductor devices may be influenced undesirably.

To manufacture a high quality silicon oxide film while decreasing the amount of thermal treatment, techniques have been proposed for modifying the film quality by processing the silicon oxide film with plasma. See, for example, WO 2002/59956 and WO 2001/69665.

### SUMMARY OF THE INVENTION

In recent years, as the semiconductor devices have been highly integrated, miniaturized and low-temperaturized, a demand on reducing the amount of thermal treatment has been increased. However, the quality of the silicon oxide film formed with low-temperature CVD method is still insufficient and a high temperature annealing treatment is indispensable. For such a reason, the demand on reducing the amount of thermal treatment has been incompatible with the improvement of the film quality of the silicon oxide film formed by CVD method.

Further, as an example of forming a silicon oxide film with CVD method, a silicon oxide thin film may be formed on an inner surface of a trench in an isolating process by Shallow Trench Isolation (STI). In the forming of the oxide film on the inner surface of the trench, the thickness of the silicon oxide film tends to be thinner at the corner of the trench, and, when the corner is an acute angle, the film may be thermalized due to concentration of electric fields and a leakage current may occur. Thus, it is understood that in order to prevent a leakage current from occurring, it is preferable to make the corner of the film to be thicker than other portions and have a round shape. However, it has been difficult to suppress the leakage current by the high temperature annealing treatment performed after the silicon oxide film is formed by CVD method, because the thickness or the shape at the corner of the trench doesn't change in spite of the high temperature annealing treatment.

The present invention is devised in consideration of the circumstances described above, and the first object of the present invention is to provide a method for modifying the film quality of an insulating film formed with CVD method or the like while minimizing the increase of the amount of thermal treatment as much as possible by processing the insulating film in a relatively lower temperature. The second object of the present invention is to provide a method for modifying the insulation film formed with a 3-dimensional shape such as an inner surface of the trench and correcting the shape of the corner.

According to the first aspect of the present invention, there is provided a method for modifying an insulating film formed on a substrate by plasma of a processing gas that contains oxygen in a processing chamber of a plasma processing apparatus. The method includes steps of introducing a processing gas containing oxygen and a noble gas into the processing chamber; introducing microwave into the processing chamber using a plane antenna having a plurality of holes; and generating plasma in the processing chamber with a plasma generating condition where O₂⁺ ions and O(¹D₂) radicals become predominant as active species in plasma, thereby modifying the insulating film.

In the method according to the first aspect of the present invention, it is preferable that a process pressure is within a range of 6.7 Pa to 267 Pa and a flow rate ratio of the oxygen over a total flow of the processing gas is within a range of 0.1% to 30%. Further, it is more preferable that in the plasma generating condition, the process pressure is within a range of 6.7 Pa to 67 Pa and a flow rate ratio of the oxygen over a total flow of the processing gas is within a range of 0.1% to 5%. Additionally, it is preferable that a processing temperature is within a range of 200° C. to 600° C. Further, it is preferable that the insulating film is a silicon oxide film formed with plasma CVD or thermal CVD.

Further, according to the second aspect of the present invention, there is provided a method for modifying an insulating film formed on a silicon layer by plasma of a processing gas that contains oxygen in a processing chamber of a plasma processing apparatus. The method includes a step of a first plasma modification process in which a processing gas containing oxygen and a noble gas is introduced into the processing chamber, microwave is introduced into the processing chamber using a plane antenna having a plurality of holes, and a first plasma is generated within a pressure range of 333 Pa to 1333 Pa, thereby oxidizing the silicon layer at an interface between the silicon layer and the insulating film with the first plasma. The method also includes a step of a second plasma modification process in which a processing gas containing oxygen and a noble gas is introduced into the processing chamber, microwave is introduced into the processing chamber using the plane antenna, and a second plasma is generated within a pressure range of 6.7 Pa to 267 Pa, thereby modifying the insulating film with the second plasma.

In the method according to the second aspect of the present invention, it is preferable that the processing pressure of the second plasma modification process is within a range of 6.7 Pa to 67 Pa. Further, it is preferable that a flow rate ratio of the oxygen over a total flow of the processing gas for the first plasma modification process is within a range of 10% to 50%. Also, it is preferable that a flow rate ratio of the hydrogen over a total flow of the processing gas for the first plasma modification process is within a range of 1% to 20%.

Additionally, in the method according to the second aspect of the present invention, it is preferable that a flow rate ratio of the oxygen over a total flow of the processing gas of the second plasma modification process is within a range of 0.1% to 30%. Also, it is preferable that a processing temperature of both the first plasma modification process and the second plasma modification process is within a range of 200° C. to 600° C. It is preferable that the insulating film is a silicon oxide film deposited with a CVD method using dichlorosilane (SiH₂Cl₂) and N₂O as raw materials.

Further, in the method according to the second aspect of the present invention, it is preferable that the silicon layer has a 3-dimensional structure having concave/convex surfaces, and the insulating film is formed along with the concave/convex surfaces. In this case, it is preferable that the silicon layer has a trench and the insulating film is formed along with the surface of the trench, and it is preferable to introduce a round shape to the corner of the trench in the first plasma modification process.

According to the third aspect of the present invention, there is provided a computer readable storage medium storing a control program that, when executed, causes a computer to control a plasma processing apparatus. The control program includes steps of introducing a processing gas containing oxygen and a noble gas into a processing chamber, introducing microwave into the processing chamber using a plane antenna having a plurality of holes, and generating plasma in the processing chamber with a plasma generating condition where O₂⁺ ions and O(¹D₂) radicals become predominant as active species in plasma, thereby modifying the insulating film.

According to the forth aspect of the present invention, there is provided a plasma processing apparatus having a processing chamber configured to process a substrate with plasma, a plane antenna having a plurality of holes configured to introduce microwave into the processing chamber, a gas supply unit configured to supply a raw gas into the processing chamber, an exhaust unit configured to depressurize and exhaust inside the processing chamber, a temperature control unit configured to control the temperature of the substrate, and a control unit configured to control a plasma modifying method to be executed in the processing chamber. The plasma modifying method includes steps of introducing a processing gas containing oxygen and a noble gas into the processing chamber, introducing microwave into the processing chamber using the plane antenna having the plurality of holes, and generating plasma in the processing chamber with a plasma generating condition where O₂⁺ ions and O(¹D₂) radicals become predominant as active species in plasma, thereby modifying the insulating film.

According to the fifth aspect of the present invention, there is provided a computer readable storage medium storing a control program that, when executed, causes a computer to control a plasma processing apparatus. The control program includes a step of a first plasma modification process in which a processing gas containing oxygen and a noble gas is introduced into a processing chamber, microwave is introduced into the processing chamber using a plane antenna having a plurality of holes, and a first plasma is generated within a pressure range of 333 Pa to 1333 Pa, thereby oxidizing the silicon layer at an interface between the silicon layer and the insulating film with the first plasma. The control program also includes a step of a second plasma modification process in which a processing gas containing oxygen and a noble gas is introduced into the processing chamber, microwave is introduced into the processing chamber using the plane antenna, and a second plasma is generated within a pressure range of 6.7 to 267 Pa, thereby modifying the insulating film with the second plasma.

According to the sixth aspect of the present invention, there is provided a plasma processing apparatus having a processing chamber configured to process a substrate using plasma, a plane antenna having a plurality of holes configured to introduce microwave into the processing chamber, a gas supply unit configured to supply a raw gas in the processing chamber, an exhaust unit configured to depressurize and exhaust inside the processing chamber, a temperature control unit configured to control the temperature of the substrate, and a control unit configured to control a plasma modifying method to be executed in the processing chamber. The plasma modifying method includes steps of introducing a processing gas containing oxygen and a noble gas into the processing chamber, introducing microwave into the processing chamber using the plane antenna having the plurality of holes, generating a first plasma with a pressure condition within a range of 333 Pa to 1333 Pa thereby oxidizing the silicon layer at an interface between the silicon layer and the insulating film with the first plasma, and generating a second plasma with a pressure condition within a range of 6.7 Pa to 267 Pa thereby modifying the insulating film with the second plasma.

According to the plasma modifying method of the first aspect of the present invention, plasma is generated by introducing microwave into the processing chamber via the plane antenna having the plurality of holes, and the insulating film is modified by plasma in which O₂⁺ ions and O(¹D₂) radicals are predominant as active species. As a result, the amount of heat treatment and plasma damage may be suppressed in a relatively low temperature, and the modified insulating film may be dense and have fewer impurities and dangling bonds. Therefore, the plasma modifying method of the first aspect of the present invention may be effective in fabricating a device such as a flash memory device having, for example, ONO structure that requires a high quality and dense insulating layer having a thickness range of 2-8 nm, suppressing the leakage current, reducing the power consumption and improving reliability.

According to the plasma modifying method of the second aspect of the present invention, in the first plasma modification process, the thickness of the insulating layer is practically increased by performing the plasma modification process with a pressure condition that ranges from 333 Pa to 1333 Pa and oxidizing the silicon which is an underlying layer of the insulating layer. In the second plasma modification process, the insulating layer having an extended thickness may be modified with plasma having a pressure range of 6.7 Pa to 267 Pa. By performing a two-step plasma modification process as described above, a silicon oxide layer having a desired thickness and fewer impurities as well as dense. Additionally, in the first plasma modification process, a rounding may be introduced to the acute angle portion (corner area) of the silicon layer having a concave/convex shape by oxidizing the interface between the insulating layer and underlying silicon layer, and changes the shape of the underlying silicon layer.

Accordingly, the plasma modifying method of the second aspect of the present invention has an effect in that the occurrence of the leakage current at the corner portion is suppressed thereby reducing the power consumption and improving the reliability in device, by applying the method to the concave/convex portions such as a liner insulating film on the inner surface of a trench in STI or a gate insulating film of a 3-dimensional structure device.

### BRIEF DESCRIPTION OF THE DRAWINGS

FIG. 1 is a diagram illustrating the schematic cross-sectional view the plasma processing apparatus to which the plasma modifying method of the present invention can be applied, as an embodiment.

FIG. 2 is a diagram illustrating the structure of the plane antenna.

FIG. 3 is a diagram illustrating the constitution of the control unit.

FIG. 4 is a flow chart illustrating the flow of the plasma modifying method according to the first embodiment of the present invention.

FIG. 5 is a diagram illustrating mimetically the modification mechanism in the plasma modification process.

FIG. 6 is a diagram illustrating mimetically a film increasing mechanism in the plasma modification process.

FIG. 7 is a plan view illustrating a schematic constitution of a substrate processing system.

FIG. 8 is a schematic cross-sectional view of a CVD apparatus as an embodiment.

FIG. 9 is a graph showing a relationship between a processing pressure of plasma modification process and a leakage current characteristic of a MOS capacitor.

FIG. 10 is a graph showing a relationship between a processing pressure of plasma modification process and a Qbd characteristic of a MOS capacitor.

FIG. 11 is a graph showing a relationship between a O₂/(Ar+O₂) ratio and a Qbd in the plasma modification process.

FIG. 12 is a schematic cross-sectional view of a flash memory device to which the plasma modifying method according to the first embodiment of the present invention can be applied.

FIGS. 13A and 13B are views each illustrating a manufacturing process of a flash memory device.

FIG. 14 is a view illustrating another manufacturing process of a flash memory device.

FIG. 15 is a view illustrating yet another manufacturing process of a flash memory device.

FIG. 16 is a flow chart illustrating the flow of the plasma modifying method according to the second embodiment of the present invention.

FIGS. 17A, 17B, 17C each illustrates an exemplary embodiment of the plasma modifying method according to the second embodiment of the present invention.

FIGS. 18A, 18B, 18C, 18D, 18E, 18F, 18G, 18H 18I illustrate one exemplary flow when the plasma modifying method according to the second embodiment of the present invention is applied to STI.

FIG. 19 is a perspective view of a 3-dimensional device to which the plasma modifying method according to the second embodiment of the present invention can be applied.

FIG. 20 is a perspective view of another 3-dimensional device to which the plasma modifying method according to the second embodiment of the present invention can be applied.

### DETAILED DESCRIPTION OF THE EMBODIMENTS

### First Embodiment

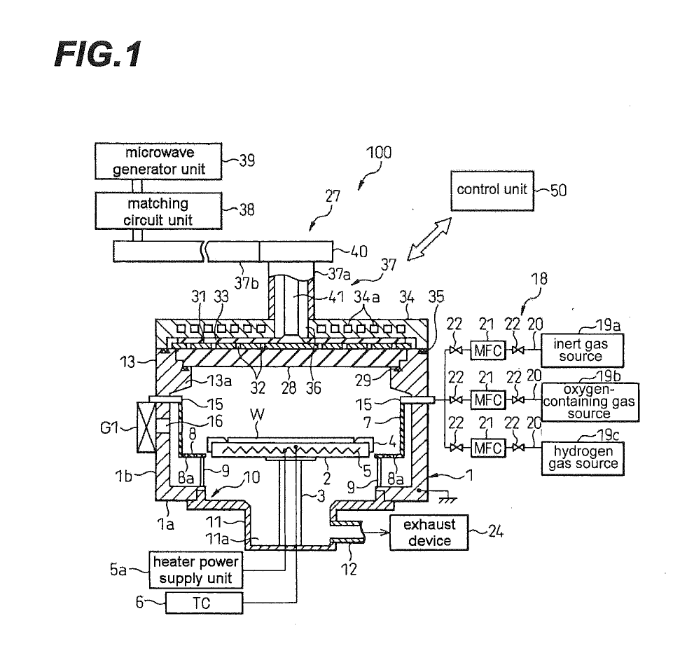

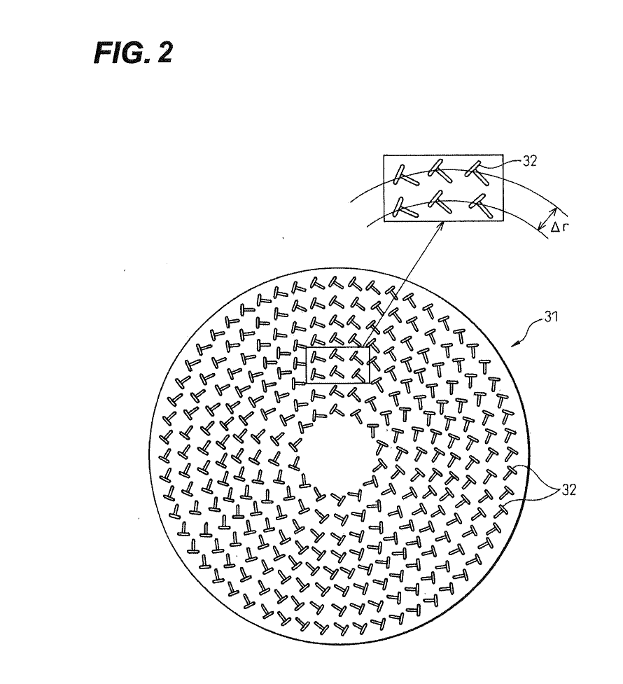

Hereinafter, embodiments of the present invention will be described in detail with reference to the accompanying drawings which form a part hereof. First of all, FIG. 1 is a cross-sectional view illustrating mimetically a schematic constitution of a plasma processing apparatus 100 applicable to the plasma modification process according to present embodiment. Also, FIG. 2 is a plan view illustrating the plane antenna of plasma processing apparatus 100 shown in FIG. 1.

Plasma processing apparatus 100 is constituted with a Radial Line Slot Antenna (RLSA) microwave plasma processing apparatus capable of generating a high density and low temperature microwave-excited plasma by introducing microwave into a processing chamber through a plane antenna having a plurality of slot-type holes, specifically, the RLSA. Because it is possible to process with plasma having a density of 1×10¹⁰ to 5×¹²/cm² and the low electron temperature of 0.7 to 2 eV, there is no plasma damage in plasma processing apparatus 100. Therefore, plasma processing apparatus 100 may be suitable to use in modifying a silicon oxide film (for example, SiO₂ film) in manufacturing a variety of semiconductor devices.

Plasma processing apparatus 100 comprises, as main components, a processing chamber 1 configured to be airtight, a gas supply device 18 for supplying gas into processing chamber 1, an exhaust device 24 for depressurizing and exhausting inside chamber 1, a microwave introduction portion 27 established on top of chamber 1 for introducing microwave into chamber 1, and a control unit 50 that controls the respective components of plasma processing apparatus 100.

Chamber 1 is built with an approximately cylindrical container which is grounded. Chamber 1 may be built with a polygonal-shaped container and has a bottom wall 1a and a side wall 1b made of a material such as aluminum.

A placing table 2 is established inside chamber 1 for holding a substrate, such as a semiconductor wafer (W) (hereinafter “wafer”), in a horizontal direction. Placing table 2 is made of a material with a high thermal conductivity, for example, ceramics, such as AlN. Placing table 2 is held by a cylindrical supporting member 3 extending upward from the center of bottom of an exhaust chamber 11. Supporting member 3 is made of ceramics, such as AlN.

Further, a cover ring 4 is disposed in placing table 2 for covering the outer edge part of placing table 2 thereby guiding wafer (W). Cover ring 4 is an annular member made of a material, such as quartz, AlN, Al₂O₃, SiN or the like.

Further, a resistance heating type heater 5 is embedded in placing table 2 as a temperature control apparatus. Heater 5 is supplied with power from a heater power supply unit 5a to heat placing table 2, thereby uniformly heating wafer (W) which is a substrate to be processed.

Further, placing table 2 is provided with a thermocouple (TC)₆. By measuring the temperature with thermocouple 6, the heating temperature of wafer (W) can be controlled within a range of, for example, a room temperature to 900° C.

Further, wafer holding pins (not shown) are disposed in placing table 2 for holding and elevating wafers (W). Holding pins for each of the wafers are installed to be capable of protruding and retreating from the surface of placing table 2.

A cylindrical liner 7 made of quartz is installed on the inner circumference of chamber 1. And, a baffle plate 8 having a number of exhaust holes 8a and made of quartz having relatively fewer impurities is formed with an annular shape on the outer circumference of chamber 1 for exhausting the inside of chamber 1 uniformly. Baffle plate 8 is supported by a plurality of hold rods 9.

A circular opening 10 is formed at approximately the center part of bottom wall 1a of chamber 1. Bottom wall 1a is provided with an exhaust chamber 11 communicating with opening 10 and protruding downwardly. Exhaust chamber 11 is connected to an exhaust pipe 12 and further connected to exhaust device 24 such as a vacuum pump through exhaust pipe 12.

A lid body 13 of which the center is opened annularly is provided on top of chamber 1 for opening and closing chamber 1. The inner circumference of lid body 13 protrudes toward inside chamber 1 to form an annular supporting part 13a.

A gas introduction portion 15 having an annular shape is established on side wall 1b of chamber 1. Gas introduction portion 15 is connected to gas supply device 18 that supplies oxygen-containing gas or plasma excitation gas. Gas introduction portion 15 may be a nozzle structure or a shower structure.

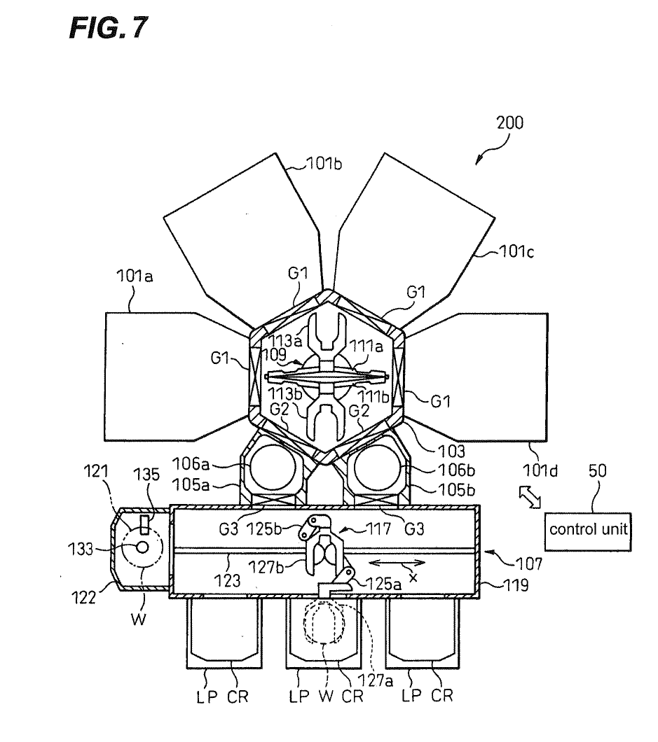

A transfer gate 16 is installed on side wall 1b of chamber 1 for carrying in and out wafers (W) between plasma processing apparatus 100 and a transfer chamber adjacent to plasma processing apparatus 100 (see FIG. 7), and a gate valve (G1) is installed for opening and closing transfer gate 16.

Gas supply device 18, for example, includes an inert gas source 19a, an oxygen-containing gas source 19b and a hydrogen gas source 19c. Gas supply device 18 may have other gas sources, such as a purge gas source used to substitute the atmosphere of chamber 1, a cleaning gas source used to clean the inside of chamber 1 and the like.

As for inert gas, for example, N₂ gas, noble gas or the like can be used. As for noble gas, for example, Ar gas, Kr gas, Xe gas, He gas or the like can be used. Among the gases, it is preferable to use Ar gas in that it generates stability plasma and is economically feasible. Additionally, as for oxygen-containing gas, for example, oxygen gas (O₂), water vapor (H₂O), nitrogen monoxide (NO) or the like can be used.

Inert gas, oxygen-containing gas and hydrogen gas reach gas introduction portion 15 from inert gas source 19a, oxygen-containing gas source 19b and hydrogen gas source 19c of gas supply device 18 through gas lines 20, and then are introduced from gas introduction portion 15 into chamber 1. Each of respective gas lines 20 connected to respective gas sources is provided with a mass-flow controller 21 and open/close valve 22 placed on the front and rear side of mass-flow controller 21. With gas supply device 18 as described herein, it is possible to convert the supplied gas, control a flow rate thereof, and so on.

Exhaust device 24 comprises a vacuum pump such as a turbo molecular pump and a high-speed vacuum pump. As described above, the vacuum pump is connected to exhaust chamber 11 of chamber 1 through exhaust pipe 12. The gas introduced into chamber 1 flows uniformly in space 11a of exhaust chamber 11 and, being exhausted from space 11a through exhaust pipe 12 upon operation of exhaust device 24. By means of this, it is possible to depressurize the inside of chamber 1 to a predetermined vacuum-level (for example, 0.1333 Pa) with a high speed.

The constitution of microwave introduction portion 27 will be explained hereinafter. Microwave introduction portion 27 is provided on lid body 13 and includes a transmission plate 28, a plane antenna 31, a wave-retardation member 33, a cover member 34, a waveguide 37, a matching circuit unit 38 and a microwave generator unit 39, as main components.

Transmission plate 28 that transmits microwave is provided on a supporting part 13a that project from lid body 13 toward the inner circumference, and formed with a dielectric material such as quartz or ceramics including Al₂O₃ and AlN. Transmission plate 28 and supporting part 13a are sealed to be airtight through a sealing member 29, thereby maintaining the inside of chamber 1 to be airtight along with lid body 13.

Plane antenna 31 is disposed above transmission plate 28 to face placing table 2, and formed with a circular plate. The shape of plane-antenna 31, which is fixed to the top end of cover 12 and grounded, is not limited to a circular plate and may be a rectangular plate.

Plane antenna 31 is made of, for example, a cooper plate or aluminum plate with the surface thereof plated with gold or silver, and has a number of slot-type microwave radiation holes 32 for radiating microwave. Microwave radiation holes 32 are formed through plane antenna 31 in a predetermined pattern.

Each of microwave radiation holes 32 is formed with a thin and elongated rectangular shape (slot-type) as shown, for example, in FIG. 2. Also, microwave radiation holes 32 are typically arranged such that adjacent microwave radiation holes 32 form a letter “T” shape. Microwave radiation holes 32 combined and arrayed to be a predetermined shape (e.g., a T-shape) as described above are also arrayed in an overall concentric shape.

Length of microwave radiation holes 32 and array intervals are determined based on the wavelength (kg) of microwave. For example, microwave radiation holes 32 may be arrayed at intervals of λg/4, λg/2, or λg. In FIG. 2, the intervals between adjacent microwave radiation holes 32 formed in a concentric shape are denoted by Ar. Microwave radiation holes 32 may have different shapes than the above, such as a circular shape, an arc shape or the like. The placing pattern of microwave radiation holes 32 is not limited to a specific one and may be arranged, for example, in a spiral shape or a radial shape, besides the concentric shape.

Wave-retardation member 33, having a dielectric constant larger than that of vacuum, is provided on the upper surface of plane antenna 31. Wave-retardation member 33 has a function of adjusting and shortening the wavelength of microwave because the wavelength of microwave becomes longer in vacuum, and is configured to introduce the microwave through microwave radiation holes 32. As for the material of wave-retardation member 33, for example, quartz, PTFE (PolyTetraFluoroEthylene) resin, polyimide resin or the like are available.

Though each pair of plane antenna 31 and transmission plate 28, and wave-retardation member 33 and plane antenna 31 may be either in contact with or separated apart from each other, may preferably be in contact with each other.

Cover member 34 is disposed on the upper portion of chamber 1 to cover plane antenna 31 and wave-retardation member 33. Cover member 34 is made of, for example, metal material such as aluminum or stainless steel, and the top of lid body 13 and cover member 34 are sealed through a shield member 35. A cooling water flow passage 34a is formed inside cover member 34 to flow cooling water thereby cooling cover member 34, wave-retardation member 33, plane antenna 31, transmission plate 28 and supporting part 13a and preventing these members from being destroyed by a thermal deformation. Also, cover member 34 is grounded.

Cover member 34 has an opening 36 formed at the center of the ceiling part which is again connected to waveguide 37. The other side of waveguide 37 is connected to microwave generator unit 39 that generates microwave through matching circuit unit 38.

Waveguide 37 is comprised of a coaxial waveguide 37a having a circular cross-section and extending upwardly from opening 36 of cover member 34, and a horizontally-extending rectangular waveguide 37b connected via a mode converter 40 at the upper end of coaxial waveguide 37a. Mode converter 40 converts the microwave propagated in a TE mode through rectangular waveguide 37b into a TEM mode.

An inner conductor 41 extends at the center of coaxial waveguide 37a, and is connected and secured to the center of plane antenna 31 at its lower end. With such construction, the microwave is propagated radially, efficiently and uniformly to inner conductor 41 of coaxial waveguide 37a and to the flat waveguide, formed by cover member 34 and plane antenna 31. The microwave in which the reflected wave thereof is suppressed at the flat waveguide is introduced from slots into the chamber.

With microwave introduction portion 27 thus constructed, the microwave generated in microwave generator unit 39 is propagated to plane antenna 31 through waveguide 38 and introduced into chamber 1 through transmission plate 28. The microwave preferably has a frequency of, for example, 2.45 GHz, and may have a frequency of 8.35 GHz, 1.98 GHz, or the like.

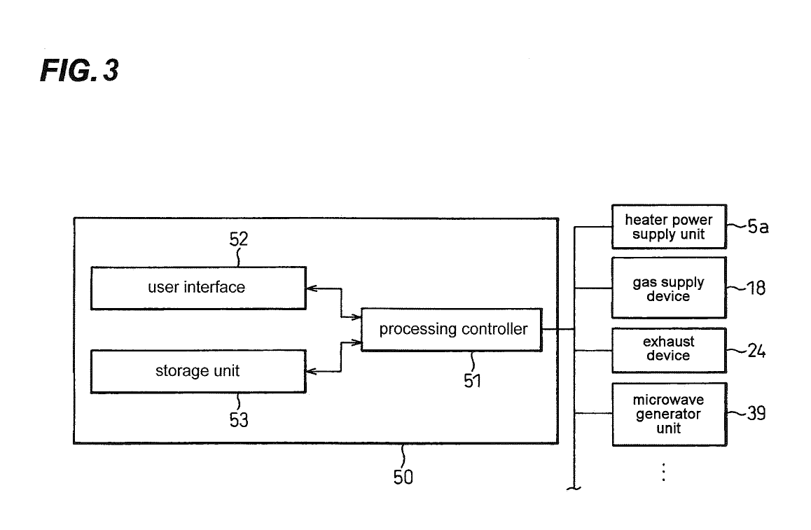

Each of the components of plasma processing apparatus 100 is connected to control unit 50 and controlled thereby. As shown in FIG. 3, control unit 50 has a computer and includes, for example, a process controller 51 provided with a CPU, a user interface 52 connected to process controller 51, and a storage unit 53. Process controller 51 is a control means which comprehensively controls each of the components [for example, heater power supply unit 5a, gas supply device 18, exhaust device 24, microwave generator unit 39, and so forth] related to processing conditions, such as temperature, pressure, gas flow rate, or output of microwave, in plasma processing apparatus 100.

User interface 52 includes a key board for a process manager to input commands in order to manage plasma processing apparatus 100, a display which visualizes and displays the operating situation of plasma processing apparatus 100 and so forth. Also, storage unit 53 stores recipes containing control program, processing condition data, and so forth recorded therein, which accomplish various processes executed in plasma processing apparatus 100 by controlling process controller 51.

As necessary, an arbitrary recipe is called out from storage unit 53 by the command of user interface 52, and executed by process controller 51 thereby a desired process is carried out in plasma processing apparatus 100 under the control of process controller 51. The recipes containing the control program and the process condition data may be used by storing in a computer readable storage medium, such as CD-ROM, hard disk, flexible disk, flash memory, DVD, BluRay disk, or the like. Alternatively, the recipes may be transmitted frequently from other apparatus online through, for example, a dedicated line.

Plasma processing apparatus 100 as described above can perform a plasma process which has no damage on the underlying film and has less amount of thermal treatment at a low temperature below 800° C., and preferably below 600° C. Moreover, since the uniformity of plasma is excellent in plasma processing apparatus 100, a uniformity of process in the surface of wafer (W) may be achieved.

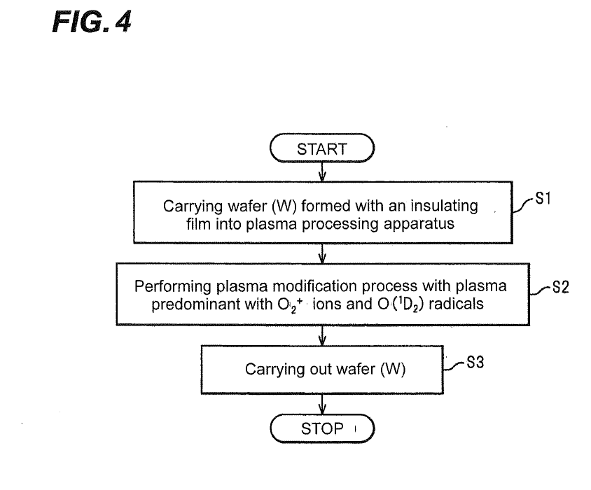

Next, an explanation will be given of a plasma modifying method according to the present embodiment in reference with the FIG. 4. FIG. 4 is a flowchart that illustrates a flow of the plasma modifying method. At first, a wafer (W) on which a silicon oxide film is formed as an insulating film is prepared and carried into chamber 1 (step S1).

Next, plasma is generated in chamber 1 of plasma processing apparatus 100 with a condition where O₂⁺ ions and O(¹D₂) radicals become predominant, thereby modifying the silicon oxide film as the insulating film with the plasma (step S2). The plasma modification process is performed in the order and the conditions as described below.

### [Sequence of the Plasma Modification Process]

First of all, while the inside of chamber 1 of plasma processing apparatus 100 is depressurized and exhausted, inert gas and oxygen-containing gas are respectively introduced at predetermined flow rates from inert gas source 19a and oxygen-containing gas source 19b into chamber 1 through gas introduction portion 15. By doing this, the inside of chamber 1 is adjusted to a predetermined pressure.

Next, a microwave having a predetermined frequency, for example, 2.45 GHz and generated in microwave generator unit 39 is induced into waveguide 37 through matching circuit unit 38. The microwave introduced into waveguide 37 sequentially passes through rectangular-shaped waveguide 37b and coaxial waveguide 37a, and then supplied to plane antenna 31 through inner conductor 41. That is, the microwave is propagated in TE mode inside rectangular waveguide 37b, converted from TE mode into TEM mode in mode converter 40, and propagated with TEM mode through coaxial waveguide 37a toward plane antenna 31. Then, the microwave is radiated from slot-type microwave radiation holes 32 formed to penetrate plane antenna 31 to the space above wafer (W) in chamber 1 through transmission plate 28.

Electromagnetic field is formed inside chamber 1 by the microwave passed through transmission plate 28 from plane antenna 31 and then radiated into chamber 1, and thereby the inert gas and the oxygen-containing gas are respectively turned into plasma. The microwave excitation plasma is turned into to plasma with a high density of about 1×10¹⁰ to 5×¹²/cm² and a low electron temperature of below about 1.2 eV around wafer (W). The high-density microwave excitation plasma formed as described above has less plasma damage by ions on the underlying film. Further, the plasma modification process is carried out for the silicon oxide film formed on the surface of wafer (W) by the action of the active species in plasma, such as O₂⁺ ions and O(¹D₂) radicals.

### [Conditions for the Plasma Modification Process]

It is preferable to use a noble gas and a oxygen-containing gas for the processing gas of the plasma modification process. It is preferable to use Ar gas for the noble gas and O₂ gas for the oxygen-containing gas. In this case, a volume flow rate ratio of O₂ gas over the total processing gas is preferably set to be within a range of 0.1% to 30% and more preferably to be within a range of 0.1% to 5%, from the viewpoint of increasing a generation efficiency of O₂⁺ ions and O(¹D₂) radicals. For example, when processing a wafer (W) with a diameter of above 200 mm, a flow rate of Ar gas may be set to be within a range of 500 to 5000 mL/min (sccm) and a flow rate of O₂ gas may be set to be within a range of 0.5 to 1000 mL/min (sccm) such that the above-described gas flow rate is met.

Further, from the viewpoint of generating O₂⁺ ions and O(¹D₂) radicals as oxidized active species in plasma with a high density, the processing pressure is preferably set within a range of 6.7 Pa to 267 Pa, and more preferably within a range of 6.7 Pa to 67 Pa.

Further, from the viewpoint of increasing a plasma density so as to generate O₂⁺ ions and O(¹D₂) radicals as much as possible to improve the stability of plasma and increase the modification rate, power density of microwave is set preferably within a range of 0.51 W/cm² to 2.56 W/cm². The power density of microwave indicates the power of microwave supplied per unit area of 1 cm² of transmission plate 28 (hereinafter, the same). For example, when processing a wafer (W) with a diameter above 200 mm, the microwave power may be preferably set to be within a range of 1000 W to 5000 W.

Also, heating temperature of wafer (W), as a temperature of placing table 2, may be set preferably within a range of 200° C. to 600° C. and more preferably to be set within a range of 400° C. to 500° C.

The above described conditions are stored as recipes in storage unit 53 of control unit 50. And, process controller 51 reads out the recipes and delivers control signals to the respective components of plasma processing apparatus 100 including gas supply device 18, exhaust device 24, microwaves generator unit 39, heater power supply unit 5a, and so forth, thereby performing the plasma modification process under a desired condition.

Next, wafer (W) completed with the plasma modification process is carried out of plasma processing apparatus 100 (step S3).

### [Action]

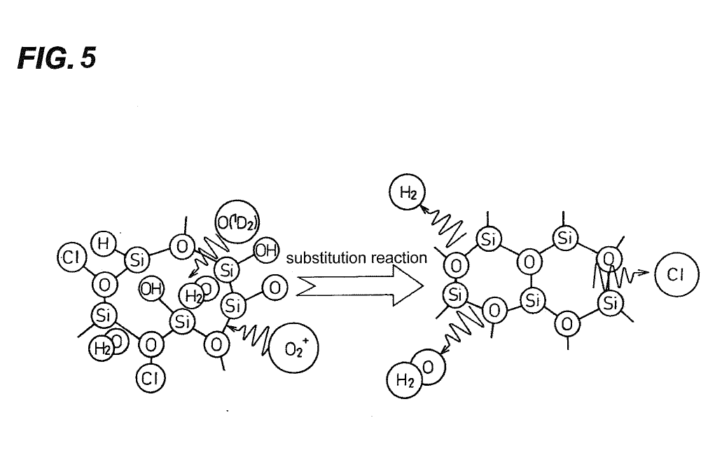

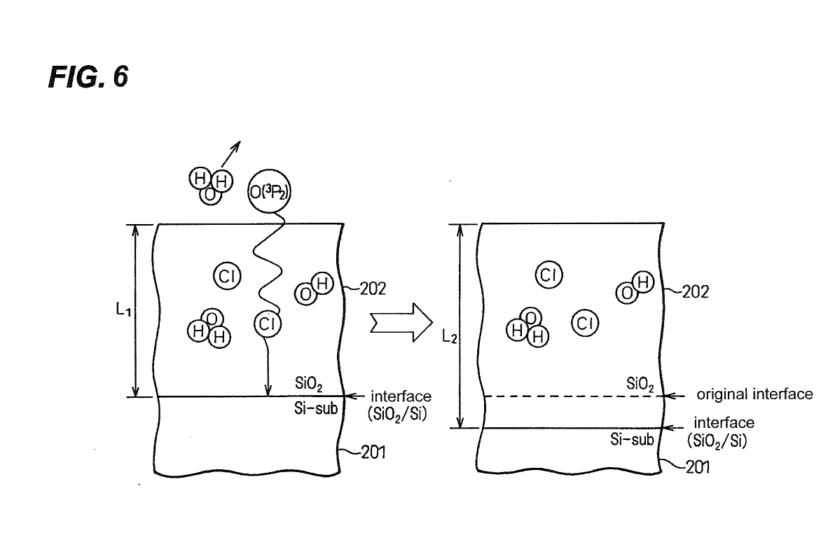

Next, an action mechanism of the plasma modification process performed under the above described conditions using plasma processing apparatus 100 will be explained with reference to FIGS. 5 and 6. When generating plasma of a processing gas containing oxygen using plasma processing apparatus 100, O₂⁺ ions, O(¹D₂) radicals and O(³Pⱼ) radicals are predominantly generated as oxidized active species. While “j” in O(³Pⱼ) radicals represents 0˜2, O(³P₂) radicals are the most generated radicals among them. Among the oxidized active species, O₂⁺ ions have a large energy (12.1 eV) and act on Si—Si bonds or bonds between Si and impurity element, thereby breaking the bonds. O(¹D₂) radicals (4.6 eV) play a principal role on Si reaction and readily enter to the Si—Si bonds or the bonds between Si and impurity elements broken by O₂⁺ ions, thereby forming a stable Si—O—Si bond. O(³Pⱼ) radicals lack energy (2.6 eV) and thus hardly contribute to the oxidation of Si. Therefore, in order to modify the silicon oxide film, plasma including a lot of O₂⁺ ions and O(¹D₂) radicals is ought to be generated. O₂⁺ ions and O(¹D₂) radicals are generated a lot more under a low processing pressure condition (below 267 Pa, preferably 6.7 Pa to 267 Pa, more preferably 6.7 Pa to 67 Pa), and the amount of generation decreases along with the increase of the processing pressure. On the other hand, the generation amount of O(³Pⱼ) radicals do not change significantly according to the processing pressure. Consequently, since plasma is generated at a low processing pressure, plasma including a lot of O₂⁺ ions and O(¹D₂) radicals is generated so that the modification on a silicon oxide film can be accomplished effectively.

FIG. 5 shows schematically chemical changes occurred in the silicon oxide film by the plasma modification process. As shown in FIG. 5, when plasma including a plurality of O₂⁺ ions and O(¹D₂) radicals acts on the silicon oxide film, O₂⁺ ions act on a dangling bond of Si first to activate the bond and then O(¹D₂) radicals make the reaction to progress easily, thereby forming a stable Si—O—Si bond. As a result, dangling bonds included in a coarse silicon oxide film are decreased, and unstable impurities included in silicon oxide film 203 such as for example, Cl, H, OH and others derived from raw material of the CVD method are discharged out of the film by the substitution with radicals. According to the above described mechanism, the silicon oxide film is modified to be a high quality film being dense and having fewer impurities and dangling bonds. Meanwhile, under the high pressure condition, O₂⁺ ions and O(¹D₂) radicals are decreased in the plasma as active species and O(³Pⱼ) radicals become predominant instead. Because O(³Pⱼ) radicals themselves are not active and tend to penetrate silicon oxide film 203, the modification effect is not excellent under the plasma generating condition where O(³Pⱼ) radicals become predominant, as compared to the modification effect where O₂⁺ ions and O(¹D₂) radicals are predominant.

As described above, under a high pressure condition (above 333 Pa, preferably 333 Pa to 1333 Pa), O₂⁺ ions or O(¹D₂) radicals are decreased in plasma as active species and O(³Pⱼ) radicals become predominant instead. O(³Pⱼ) radicals are not active themselves but, as shown in FIG. 6, have a property of penetrating silicon oxide film 202, and reach an interface between silicon oxide film 202 and an underling silicon layer 201 to accelerate the oxidization of silicon layer 201. In particular, O(³Pⱼ) radicals tend to penetrate easily a low quality coarse film of silicon oxide film 202 such as a porous film or a film formed by plasma CVD which comes to be a target of the plasma modification process, thereby causing the oxidization of underling silicon layer 201. On this account, a radical oxidation goes along on the interface between porous silicon oxide film 202 and underling silicon layer 201, thereby increasing the thickness of porous silicon oxide film 202 from L₁ to L₂ under a high pressure condition. This inclination may be even more strengthened by including hydrogen into the processing gas.

In the plasma modifying method of the present embodiment, based on the understanding that the active species in plasma vary according to the processing pressure as described above, an improved modification effect can be obtained for a porous silicon oxide film by performing the plasma modification process at a low pressure condition (below 267 Pa) where high density O₂⁺ ions and O(¹D₂) radicals are generated.

Next, referring to FIG. 7, a substrate processing system will be explained which can be readily utilized to perform the plasma modifying method according to the present embodiment. FIG. 7 is a view illustrating a schematic constitution of a substrate processing system 200 configured to perform various processes for wafer (W) such as, for example, a film forming process, a modification process and so forth. Substrate processing system 200 is constituted as cluster tools with a multi-chamber structure.

Substrate processing system 200 comprises, as main components, four process modules 101a, 101b, 101c, 101d that include a process vessel for performing various processes for wafer (W), a vacuum-side transfer chamber 103 connected through a gate valve (G1), two load-lock chambers 105a, 105b connected to transfer chamber 130 through a gate valve (G2), and a loader unit 107 connected to two load-lock chambers 105a, 105b through a gate valve (G3).

Four process modules 101a-101d are the processing apparatus that perform, for example, a CVD process and a plasma modification process for wafer (W). In the present embodiment, process modules 101a-101d are configured at least to perform a film forming process for wafer (W) by CVD method and a plasma modification process by acting the plasma to the silicon oxide film formed by the above film forming process.

A transfer device 109 is installed at vacuum-side transfer chamber 103 as a first substrate transfer device for transferring wafer (W) to process modules 101a-101d and load-lock chambers 105a, 105b. Vacuum-side transfer chamber 103 is configured to be vacuum-exhausted. Transfer device 109 includes a pair of transfer arms 111a, 111b arranged to face each other, and each of transfer arms 111a, 111b is configured to be bendable, extendable and rotatable about the same rotational shaft. Moreover, forks 113a, 113b are provided at the front end of each of transfer arms 111a, 111b for arranging and supporting wafer (W). Transfer device 109 transfers wafer (W) either between process modules 101a-101d or between process modules 101a-101d and load-lock chambers 105a, 105b in a state where wafer (W) is arranged on forks 113a, 113b.

Placing tables 106a, 106b with wafer (W) arranged thereon are provided in each of load-lock chambers 105a, 105b configured to be converted between a vacuum state and an atmosphere opening state. Wafers (W) are exchanged between vacuum-side transfer chamber 103 and an atmosphere-side transfer chamber 119 (which will be described below) with placing tables 106a, 106b of the load-lock chambers 105a, 105b interposed.

A loader unit 107 includes atmosphere-side transfer chamber 119 provided with a transfer device 117 as a second substrate transfer device for transferring the wafer (W), three load ports (LP) arranged adjacent to atmosphere-side transfer chamber 119, a chamber 122 having a position detecting device (orientor; 121) arranged at the other side of atmosphere-side transfer chamber 119 that measures the position of the wafer (W).

Atmosphere-side transfer chamber 119, for example, is equipped with circulation facilities (not shown) for forming a clean environment by down-flowing nitrogen gas or clean air, thereby maintaining a clean environment. Atmosphere-side transfer chamber 119 is made of a rectangular shape in a plain view and is provided with a linear rail 123 along with the longitudinal direction which supports transfer device 117 so that transfer device 117 can be slide-movable. That is, transfer device 117 is configured to be movable in the X direction along with linear rail 123 by a driving device which is not shown. Transfer device 117 includes a pair of transfer arms 125a, 125b arranged in a two-step of up and down and each of transfer arms 125a, 125b is configured to be bendable, extendable, and rotatable. Forks 127a, 127b are provided at the front end of each of transfer arms 125a, 125b. Transfer device 117 transfers the wafer (W) between a wafer cassette (CR) of the load port (LP), load-lock chambers 105a, 105b, and position detecting device 121. The load port (LP) is configured to install the wafer cassette (CR) and the wafer cassette (CR) is configured in such a way that a plurality of wafers are arranged at the same intervals and in multi-stages.

Position detecting device 121 comprises a rotation plate 133 rotated by a drive motor which is not shown and an optical sensor 135 installed at the periphery of rotation plate 133 for detecting the edge of the circumference of the wafer (W).

In the present embodiment, process modules 101a, 101c are configured to perform the plasma modification process of the present invention to modify an insulating film by utilizing plasma modifying apparatus 100. Process modules 101b, 101d are also configured to perform a CVD process for forming an insulating film such as a silicon oxide film on the wafer (W). Alternatively, every process modules 101a-101d may be constituted to perform the plasma modification process.

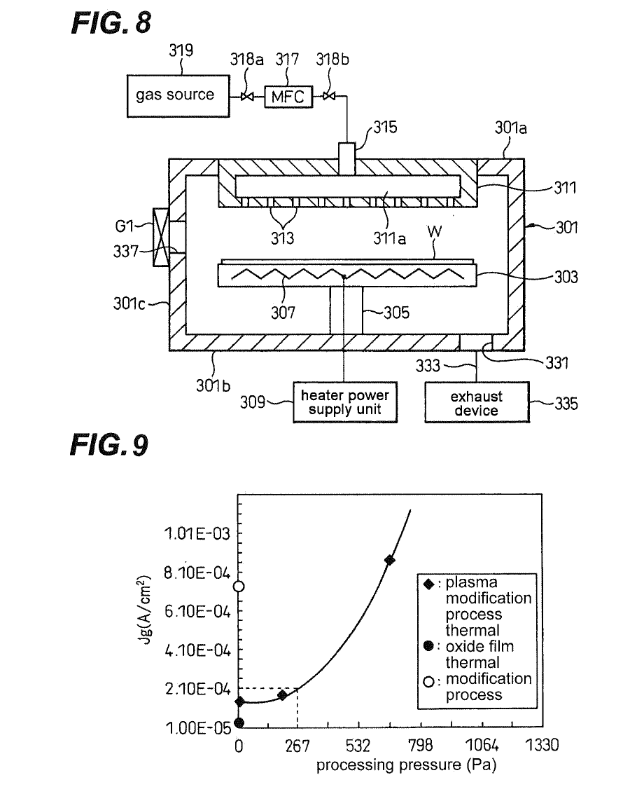

An exemplary schematic constitution of a single wafer type CVD film forming apparatus 300 is illustrated in FIG. 8 which can be act as process modules 101b, 101d. Single wafer type CVD film forming apparatus 300 includes an approximately cylindrical processing chamber 301 configured to be airtight, and a placing table (susceptor; 303) is arranged inside processing chamber 301 for holding the wafer (W) as a substrate in a horizontal state. Placing table 303 is supported by a cylindrical hold member 305 and embedded with a heater 307. Heater 307 is supplied with power from a heater power supply unit 309 to heat the wafer (W) at a predetermined temperature.

An opening and closing ceiling wall 301a of processing chamber 301 is equipped with a shower head 311. Shower head 311 has a gas diffusion space 311a inside thereof, and a number of gas discharge holes communicating with gas diffusion space 311a are formed on the bottom surface of shower head 311. And, a gas supply pipe 315 communicating with gas diffusion space 311a is connected to the center portion of shower head 311. Gas supply pipe 315 is connected, through a mass-flow controller (MFC; 317) and valves 318a, 318b placed on back and forth thereof, to a gas source 319 that supplies raw gas such as dichlorosilane (SiH₂Cl₂), N₂O for a film forming, or supplies a purge gas for substituting the atmosphere of processing chamber 301. And, the raw gas of the film forming is supplied to shower head 311 through gas supply pipe 315 and mass-flow controller 317.

An exhaust hole 331 is formed on bottom wall 301b of processing chamber 301 and an exhaust device 335 is connected to exhaust hole 331. Further, exhaust device 335 is configured to depressurize the inside of processing chamber 301 to a predetermined vacuum level by exhaust device 335. Raw gas supplied to processing chamber 301 through shower head 311 may become plasma for forming a film by supplying a high frequency electric power to shower head 311 from a high frequency power supply (not shown).

Additionally, a carrying in/out opening 337 for carrying in and out the wafer (W) is formed on side wall 301c of processing chamber 301 and the wafer (W) is carried in and out through carrying in-and-out opening 337. Gate valve (G1) opens and closes carrying in-and-out opening 337.

In single wafer CVD film forming apparatus 300 with the constitution as described above, the wafer (W) is arranged on placing table 303, and a thin film of, for example, SiO₂ film can be formed on the surface of the wafer (W) with the CVD method by supplying the raw gas from shower head 311 toward the wafer (W) while heating the wafer (W) by heater 307.

Single wafer CVD film forming apparatus 300 with the constitution as described above is also controlled by control unit 50 (see FIG. 3). The CVD film forming apparatus is not limited to a single wafer type but may be a batch type film forming apparatus.

In substrate processing system 200, a CVD process and a plasma modification process are performed in the following order. First, a sheet of wafer (W) is carried out of the wafer cassette (CR) of the load port (LP) using one of forks 127a or 127b of transfer device 117 in atmosphere-side transfer chamber 119, positioned in position detecting device 121, and then carried into a load-lock chamber 105a or 105b. Gate valve (G3) is closed in load-lock chamber 105a or 105b in a state that the wafer (W) is arranged on placing table 106a or 106b, so load-lock chamber 106a or 106b is depressurized and exhausted to be a vacuum state. Thereafter, gate valve (G2) is opened and the wafer (W) is carried out of load-lock chamber 105a or 105b by fork 113 of transfer device 109 in vacuum-side transfer chamber 103 and then carried into one of process modules 101a-101d.

The wafer (W) carried out of load-lock chamber 105a or 105b by transfer device 109 is carried into one of process modules 101a-101d and a CVD process is performed for the wafer (W) after gate valve (G1) is closed.

Successively, gate valve (G1) is opened and the wafer (W) formed with an insulating film is carried into one of process modules 101a or 101c from process module 101b or 101d by transfer device 109 in a vacuum state. Then, a plasma modifying process is performed for the above insulating film after gate valve (G1) is closed. Next, gate valve (G1) of process module 101a or 101c is opened so the wafer (W) processed with the plasma modification process is carried out by transfer device 109 and then carried into load-lock chamber 105a or 105b. Thereafter, the wafer (W) completed with the processes is stored in the wafer cassette (CR) of the load port (LP) in a reverse order to the above so processes for one sheet of wafer (W) in substrate processing system 200 is completed. As described above, substrate processing system 200 as an example is equipped with two of single wafer CVD film forming apparatuses 300 and two of plasma processing apparatuses 100, thereby making it possible to perform the CVD process for forming an insulating film and the plasma modification process continuously while maintaining a vacuum state. The respective processing apparatuses in substrate processing system 200 may be constituted of any arrangements as long as the substrate processing system has the number of chamber and the arrangement which make it possible to process effectively. Moreover, the number of process modules in substrate processing system 200 is not limited to four but may be more than two as long as the processing system can be operated effectively.

Next, a description will be made for experimental data on which the present invention is based. Using plasma modifying apparatus 100 shown in FIG. 1, a silicon oxide film formed with thermal CVD method is modified with plasma under conditions 1 through 4 (plasma modification process). An increased amount of thickness, an increased amount of refractive index, and a wet etching rate by a 0.125% dilute hydrofluoric acid process (for 30 seconds) have been investigated regarding with the silicon oxide film after the modification. Also, a MOS capacitor has been manufactured using the silicon oxide film as a gate insulator after the modification and then a leakage current density (Jg: −10 MV/cm), an insulation breakdown charge [Qbd: 63% (this means data that the number which is 63% of total indicates), and a variation of an electron trapping (Δvge: 11 seconds) have been investigated as electric characteristics. For comparison, similar measurements have been made for the cases where a plasma modification process has not been performed, modification process has been performed only by annealing (thermal modification process), and for the case of thermal oxide film (WVG: Water Vapor Generation method). The results are shown in Table 1.

[Plasma Modification Process Condition 1]

Ar gas flow rate: 1000 mL/min (sccm)

O₂ gas flow rate: 300 mL/min (sccm)

Flow rate ratio (O₂/Ar+O₂): 0.23

Processing pressure: 6.7 Pa

Temperature of placing table: 500° C.

Microwave power: 4000 W

Microwave power density: 2.05 W/cm² (per 1 cm² area of transmitting plate)

[Plasma Modification Process Condition 2]

Ar gas flow rate: 1980 mL/min (sccm)

O₂ gas flow rate: 20 mL/min (sccm)

Flow rate ratio (O₂/Ar+O₂): 0.01

Processing pressure: 200 Pa

Temperature of placing table: 500° C.

Microwave power: 4000 W

Microwave power density: 2.05 W/cm² (per 1 cm² area of transmitting plate)

[Plasma Modification Process Condition 3]

Ar gas flow rate: 1200 mL/min (sccm)

O₂ gas flow rate: 400 mL/min (sccm)

Flow rate ratio (O₂/Ar+O₂): 0.25

Processing pressure: 667 Pa

Temperature of placing table: 500° C.

Microwave power: 4000 W

Microwave power density: 2.05 W/cm² (per 1 cm² area of transmitting plate)

[Plasma Modification Process Condition 4]

Ar gas flow rate: 1200 mL/min (sccm)

O₂ gas flow rate: 370 mL/min (sccm)

H₂ gas flow rate: 30 mL/min (sccm)

Flow rate ratio (O₂/Ar+O₂+H₂): 0.23

Flow rate ratio (H₂/Ar+O₂+H₂): 0.019

Processing pressure: 667 Pa

Temperature of placing table: 500° C.

Microwave power: 4000 W
Microwave power density: 2.05 W/cm² (per 1 cm² area of transmitting plate)

[Annealing Modification Process Condition]

Atmosphere: N₂/O₂

Temperature: 900° C.

Pressure: 133 Pa

[Thermal Oxide Film Forming Condition]

Atmosphere: H₂/O₂=450/900 mL/min (sccm)

Temperature: 950° C.

Pressure: 15000 Pa

[Thermal CVD Film Forming Condition]

SiH₂Cl₂ gas flow rate: 75 mL/min (sccm)

N₂O gas flow rate: 150 mL/min (sccm)

Processing pressure: 48 Pa

Processing temperature: 780° C.

TABLE 1

| | Variance of | Variance of | Etching rate |
|---|---|---|---|
| Classification | Thickness [nm] | Refractive index | [nm/min] |
| Plasma Modification | −0.0356 | 0.018 | 1.4916 |
| Process Condition 1 | | | |
| Plasma Modification | 0.0581 | 0.012 | 1.5068 |
| Process Condition 2 | | | |
| Plasma Modification | 1.0749 | 0 | 2.5952 |
| Process Condition 3 | | | |
| Plasma Modification | — | — | 3.0596 |
| Process Condition 4 | | | |
| Thermal Modification | — | — | 2.4904 |
| Process by Annealing | | | |
| Thermal Oxide Film | — | — | 1.0504 |

From the physical analysis shown in Table 1, the refractive index is increased and the wet etching rate is decreased when the plasma modification process has been performed under the condition 1 and the condition 2 where the pressure is below 200 Pa. Such data show that the quality of the silicon oxide film has been improved by the plasma modification process so that the film density has been increased. And, comparing the conditions 1 and 2 of the plasma modification process with the modification process performed only by thermal annealing, it is represented that the modification processes under the conditions 1 and 2 have a higher modification effect because the wet etching rate thereof is lower than the thermal modification process. It is thought that impurities and dangling bonds in the film have been reduced by the plasma-generated O₂⁺ and O(¹D₂) radicals and the film became denser.

And, when the plasma modification process has been performed under the condition 4, the variation of the refractive index has not been observed, and the wet etching rate has been almost the same as the thermal modification process. That is, with regards to the improvement effect on the film quality, the results of the plasma modification process under the condition 4 appear to be the same as the thermal modification process. However, when the plasma modification process has been performed under the condition 4, the generation of O₂⁺ and O(¹D₂) appears to be reduced due to the high processing pressure so that the modification effect is low and the increase in thickness of the silicon oxide film has been observed. It appears that the interface between the silicon oxide film formed with CVD method and the underlying silicon has been oxidized by O(³Pⱼ) radicals thereby increasing the film thickness.

The above results indicate that, a low pressure condition such as, for example, 6.7 Pa to 267 Pa is preferable and a range of 133 Pa to 267 Pa is more preferable from the viewpoint that it is easy to generate O₂⁺ and O(¹D₂) radicals. And, in the plasma modification process under this condition, the film quality of the silicon oxide film formed with CVD method appears to have a high modification effect. Meanwhile, when the plasma modification process has been performed under the high pressure condition where the processing pressure is above 267 Pa, it has been confirmed that the modification effect for the film quality of the silicon oxide film is low similar to the thermal modification process and the thickness of the film has been increased.

TABLE 2

| | Pressure | O₂/(Ar + O₂) | J g | Q b d | Δ v g e |
|---|---|---|---|---|---|
| Classification | [Pa] | ratio | [A/cm²] | [C/cm²] | [11 sec] |
| Plasma Modification Process Condition 1 | 6.7 | 0.23 | 1.44 × 10⁻⁴ | 33.1 | −0.13 |
| Plasma Modification Process Condition 2 | 200 | 0.01 | 1.74 × 10⁻⁴ | 51.5 | −0.12 |
| Plasma Modification Process Condition 3 | 667 | 0.25 | 8.50 × 10⁻⁴ | 10.2 | −0.19 |
| Thermal Modification Process by Annealing | 133 | — | 7.57 × 10⁻⁴ | 1.2 | −0.20 |
| Thermal Oxide Film | | | 3.00 × 10⁻⁵ | 44.0 | 0.02 |

From the results of the evaluation of the electric characteristics shown in Table 2, the leakage current has been drastically reduced when the plasma modification process has been performed under the conditions 1 and 2 of low pressure, as compared to the condition 3 of high pressure and the thermal modification process. The results are attributable to the fact that impurities and dangling bonds in the film have been reduced due to O₂⁺ and O(¹D₂) radicals and the film has been modified to be dense. Also, when the plasma modification process has been performed under the condition 3 of high pressure, the reduction effect of the leakage current has been low which has been almost the same as the thermal modification process. It has been considered that the generation of O₂⁺ and O(¹D₂) radicals has been reduced due to the high processing pressure, and the application effect of the O₂⁺ and O(¹D₂) radicals is trivial.

A relationship between the processing pressure of the plasma modification process under the conditions 1 through 3 and the leakage current is shown in FIG. 9. And, FIG. 9 also shows the leakage current of the annealing modification process and the thermal oxide film. It is understood that the leakage current can be suppressed to below 2.1×10⁻⁴ [A/cm²] if the processing pressure is below 267 Pa e.g., 6.7 Pa to 267 Pa, and more preferably within a range of 133 Pa to 267 Pa.

Therefore, the processing pressure of the plasma modification process may be set to below 267 Pa for the purpose of improving the characteristic of the leakage current.

An insulation breakdown charge (Qbd) has been drastically improved by the plasma modification process under the conditions 1 through 3 as compared with the thermal modification process. In particular, when the plasma modification process is performed under the condition 2, an excellent reliability has been shown which is superior to the thermal oxide film.

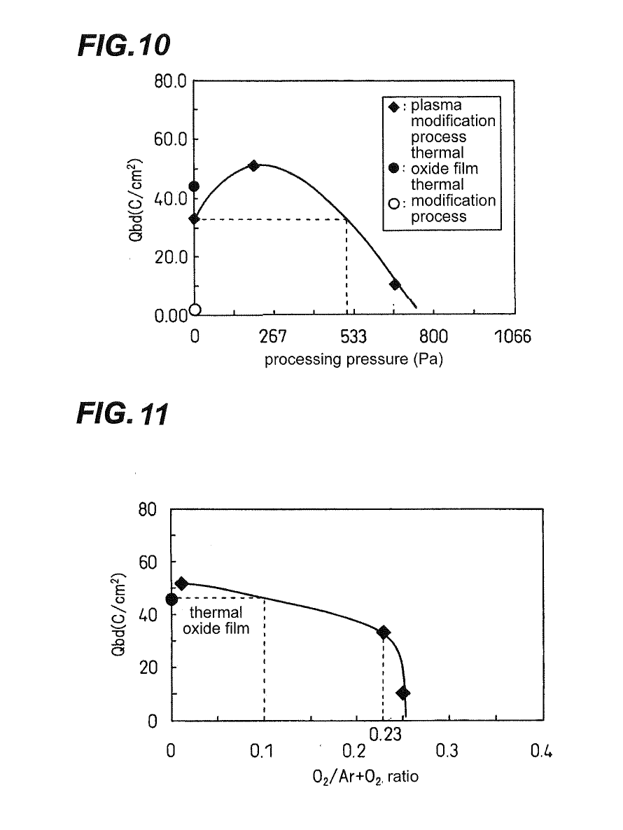

A relationship between the processing pressure of the plasma modification process under the conditions 1 through 3 and the Qbd is shown in FIG. 10. From FIG. 10, it is understood that the Qbd can be above 33 [C/cm²] when the processing pressure is below 533 Pa. Therefore, the processing pressure of the plasma modification process may be set to be below 533 Pa e.g., 6.7 Pa to 533 Pa, 6.7 Pa to 400 Pa, or 6.7 Pa to 267 Pa.

Further, a relationship between the (O₂/Ar+O₂) ratio of the plasma modification process under the conditions 1 through 3 and the Qbd is shown in the FIG. 11. As shown in FIG. 11, it is confirmed the Qbd characteristic may be effectively improved by setting the (O₂/Ar+O₂) ratio below 0.23 and more preferably within a range of 0.1 to 0.23, and, in particular, a high Qbd characteristic may be achieved exceeding the thermal oxide film by setting the (O₂/Ar+O₂) ratio below 0.1.

From Table 2, it can be understood that, when the plasma modification process is performed under the conditions 1 and 2, the variation of the electron trapping (Δvge: 11 seconds) has been reduced nearly to half as compared to the thermal modification process thereby being largely improved. When the plasma modification process is performed under the condition 3, the variation of the electron trapping has been slightly improved as compared to the thermal modification process. Therefore, it is confirmed that the characteristic of Δvge can be improved effectively by setting the (O₂/Ar+O₂) ratio below 0.23 and more preferably within a range of 0.1 to 0.23.

From the results as described above, it can be confirmed that the plasma modification process can modify the quality of the silicon oxide film either to be the same as or better than the thermal oxide film. Particularly, it is confirmed that if plasma is generated under the low pressure condition of below 267 Pa such as, for example, 6.7 Pa to 267 Pa and more preferably within a range of 133 Pa to 267 Pa, O₂⁺ and O(¹D₂) radicals are predominantly generated and the plasma modification process is carried out with the generated plasma to obtain the excellent modification effect for the dense silicon oxide film due to the action of O₂⁺ and O(¹D₂) radicals. It is also confirmed that reliability in the electric characteristics of a device can be improved by using the modified silicon oxide film as described above.

Next, the variation of the residue of chlorine (originated from the raw material of SiH2C12), caused by the plasma modification process, inside the silicon oxide film formed with CVD method has been considered. The residue of the chlorine in the silicon oxide film has been measured by Total reflection X-ray Fluorescence (TXRF) analysis. Results are shown in Table 3.

TABLE 3

| | Residue of Chlorine |
|---|---|
| Classification | [atoms/cm²] |
| Plasma Modification Process | 1.0 × 10¹³ |
| (Modification Condition 2) | |
| No Modification Process | 5.60 × 10¹³ |

Table 3 shows that, when the plasma modification process is performed, the residue of chlorine has been reduced to one fifth as compared to the case when there was no modification process indicating that impurities in the silicon oxide film can be removed by the plasma modification process. A thermal annealing process may be performed after the plasma modification process. Also, the residue of chlorine may be reduced to 9.60×10¹¹ [atoms/cm²] by combining the plasma modification process and the thermal annealing process.

As described above, in the plasma modifying method of the present embodiment, the range of film thickness which has a high modification effect on the silicon oxide film is, for example, 2-8 nm. And, the high quality silicon oxide film being dense and having a high reliability formed with the plasma modification process of the present embodiment may be available to necessary applications. As examples of such applications, the plasma modification process may be applied as a post-process to the silicon oxide film formed as an interlayer insulating film formed with CVD method or plasma CVD method.

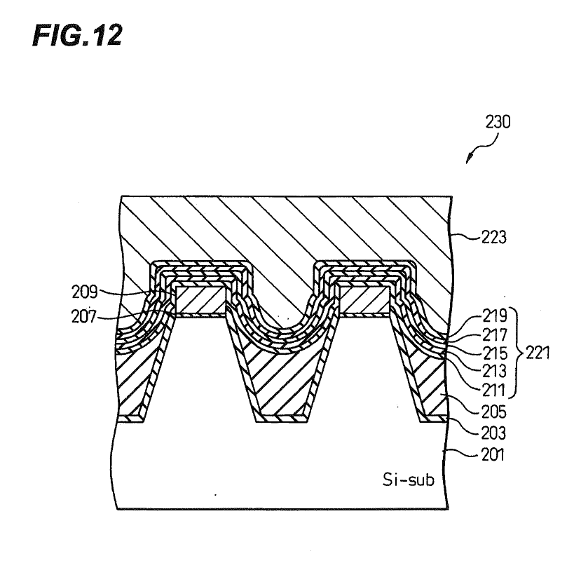

FIG. 12 is a cross-sectional view illustrating a schematic constitution of a flash memory 230 having an ONO (silicon oxide film-silicon nitride oxide film-silicon oxide film) structure. A liner silicon oxide film 203 is formed on a silicon substrate 201 having a concave/convex shape, and an insulating film 205 is embedded inside the concave portion by a spin-on-dielectric (SOD). A floating gate electrode 209 made of, for example, poly-silicon is formed on the convex portion of silicon substrate 201 by interposing a gate insulating film 207. Floating gate electrode 209 is covered with a laminated insulating film 221 composed of five layers of insulating films which are, from the bottom, a silicon nitride film 211, a silicon oxide film 213, a silicon nitride film 215, a silicon oxide film 217, and a silicon nitride film 219. Moreover, a control gate electrode 223 made of, for example, poly-silicon is formed on laminated insulating film 221.

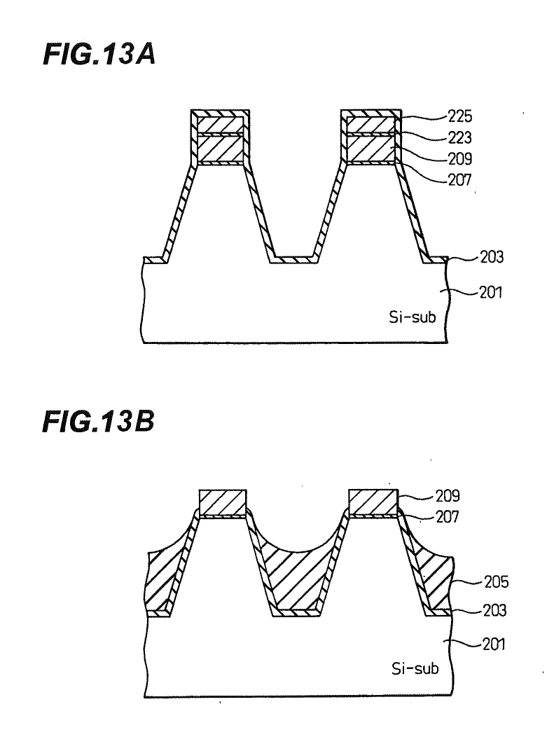

In the present embodiment, liner silicon oxide film 203 and silicon oxide films 213, 217 of laminated insulating film 221 are formed with CVD method and then the plasma modification process according to the method of the present invention is performed for the above films. The plasma modification process is capable of modifying liner silicon oxide film 203 and silicon oxide films 213, 217 to a high quality silicon oxide film being dense and having fewer impurities. FIG. 13A, for example, illustrates that liner silicon oxide film 203 formed with the CVD method on silicon substrate 201 formed with floating gate electrode 209. In FIG. 13A, mark 223 denotes a silicon oxide film and mark 225 denotes a hard mask film such as a silicon nitride film. In step of FIG. 13A, liner silicon oxide film 203 may be modified with plasma using plasma modifying apparatus 100, thereby making the film quality to be dense and removing the impurities.

FIG. 13B shows a continuing state from FIG. 13A where insulating film 205 is formed by SOD, wet-etched by a diluted hydrofluoric acid, and etched back. In this etch-back process, it is important to obtain a sufficient etching selectivity between liner silicon oxide film 203 and insulating film 205 formed by SOD. That is, in the wet etching process, liner silicon oxide film 203 should be remained by making the etching rate of liner silicon oxide film 203 lower than that of insulating film 205 formed by SOD. On this account, it is important to process liner silicon oxide film 203 by the plasma modifying method according to the present invention to make the film dense.

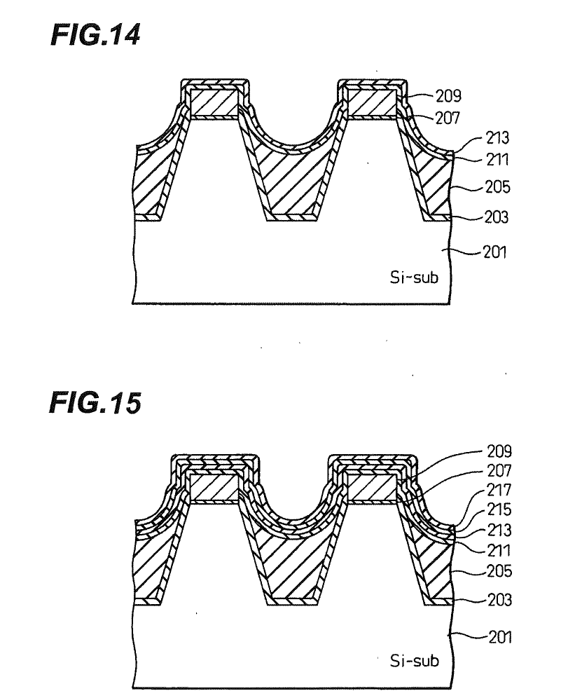

Further, FIG. 14, for example, illustrates the state thereafter of forming silicon oxide film 213 including laminated insulating film 221 with the CVD method. Silicon oxide film 213 becomes a bottom oxide film of the lower side of the ONO structure. Meanwhile, FIG. 15 similarly illustrates the state of forming silicon oxide film 217 which becomes a top oxide film of the ONO structure formed with the CVD method. The leakage current from control gate electrode 223 to floating gate electrode 209 or to silicon substrate 201 can surely be reduced by modifying silicon oxide films 213, 217 including laminated insulating film 221 through the plasma modification process using plasma processing apparatus 100. As described above, the plasma modifying method of the present invention may be applied to the process of manufacturing flash memory 230, thereby reducing the power consumption of flash memory 230 and improving the reliability of device.

### Second Embodiment

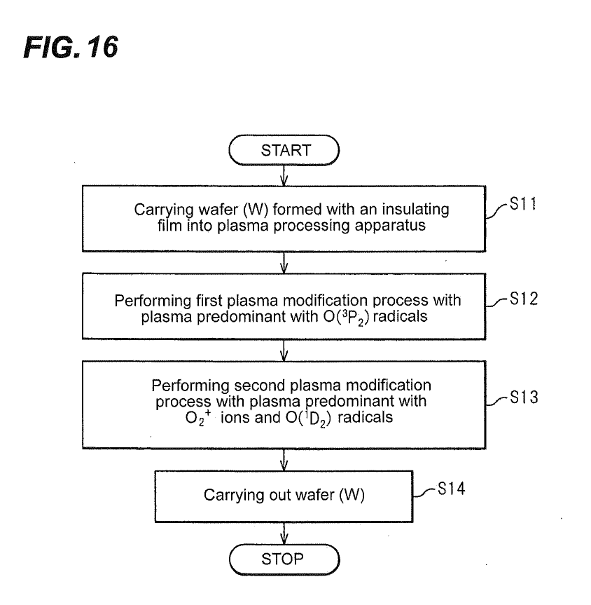

Next, the plasma modifying method according to the second embodiment of the present invention will be explained with reference to FIGS. 16 through 20. FIG. 16 is a flowchart showing an exemplary flow of the plasma modifying method according to the second embodiment of the present invention. In the above first embodiment, the plasma modification process is performed under the low pressure condition of below 267 Pa, for example, 6.7 Pa to 267 Pa, thereby modifying the silicon oxide film formed with the CVD method to a high quality film being dense and having fewer impurities. However, in the present embodiment, it is constituted that prior to the plasma modification process under the low pressure condition, the plasma modification process is performed under a high pressure condition using plasma modifying apparatus 100.

In FIG. 16, a wafer (W) formed with a silicon oxide film as an insulating film is carried into plasma modifying apparatus 100 at first. Next, in step S12, plasma in which O(³Pⱼ) radicals are predominant is generated inside chamber 1 (processing chamber) of RLSA type plasma processing apparatus 100 as shown in FIG. 1, and performs the first plasma modification process for the silicon oxide film by the plasma (the first plasma modification process). The first plasma modification process is performed under the conditions as described below using plasma modifying apparatus 100. The flow of the first modification process by plasma modifying apparatus 100 may be applied correspondingly to step S2 (FIG. 4) of the first embodiment, and hence a description thereof will be omitted herein.

### [Conditions of the First Plasma Modification Process]

It is preferable to use gas including a noble gas, an oxygen-containing gas, and hydrogen as a processing gas of the plasma modification process. Because H or OH radicals generated by including hydrogen in the processing gas have a rapid solid solubility and diffusion velocity for a silicon dioxide (SiO₂), the thickness of the silicon oxide film can be increased. Ar gas is preferably used as for the noble gas and O₂ gas is preferably used as for the oxygen-containing gas. In this case, a volume flow ratio of O₂ gas over the total processing gas is preferably set to be within a range of 10% to 50% and more preferably set to be within a range of 30% to 50%, in view of increasing the generation efficiency of O(³Pⱼ) radicals.

Further, a volume flow ratio of H₂ gas over the total processing gas is preferably set to be within a range of 1% to 20% and more preferably set to be 1% to 10%, in the view of increasing the modification rate.

For example, a flow rate of Ar gas may be set to be within a range of 500 mL/min (sccm) to 5000 mL/min (sccm), a flow rate of O₂ gas may be set to be within a range of 5 mL/min (sccm) to 500 mL/min (sccm), and a flow rate of H₂ gas may be set to be 1 mL/min (sccm) to 300 mL/min (sccm) such that the above-described gas flow ratio is met.

Further, the processing pressure is preferably within a range of 333 Pa to 1333 Pa and more preferably within a range of 400 Pa to 667 Pa in the view of obtaining the film with increased thickness by generating plasma in which radicals such as O(³P₃) are predominant.

Further, a power density of microwave is preferably set to be within a range of 2 W/cm² to 3 W/cm² in view of increasing the reliability or uniformity of plasma. A microwave power is preferably set to be within a range of 2000 W to 5000 W.

Further, the temperature of wafer (W) is preferably set to be within a range of 200° C. to 600 t and more preferably within a range of 400° C. to 500° C.

By performing the first plasma modification process of step S12 within the range of the above described condition, the interface between the silicon oxide film formed with the CVD method and the underling silicon is oxidized, thereby increasing the thickness of the silicon oxide film substantially. By increasing the film thickness, it is possible to adjust the shape of the interface of the silicon oxide film formed on, for example, the silicon having a concave/convex shape, and to introduce a round shape into the corner of the concave/convex shape.

Next, in step S13, a second plasma modification process is performed for the thickness-increased silicon oxide film under the condition where the pressure is lower than that of the first plasma modification process such as, for example, below 267 Pa, preferably 6.7 Pa to 267 Pa, more preferably 6.7 Pa to 67 Pa using plasma modifying apparatus 100, where plasma predominant with O₂⁺ ions and O(¹D₂) radicals is generated. By the second plasma modification process, it is possible to make the quality of the thickness-increased silicon oxide film to be dense and to form the high quality silicon oxide film having fewer impurities. The conditions and the order of the second plasma modification process are the same as the plasma modification process of step S2, and hence the description thereof will be omitted.

The conditions of the first plasma modification process and the second plasma modification process are stored in storage unit 53 of control unit 50 as recipes. Then, process controller 51 reads out the recipes and transmits control signals to the respective components of plasma processing apparatus 100 such as gas supply device 18, exhaust device 24, microwave generator unit 39, heater power supply unit 5a and so forth to perform the plasma modification process under a desired condition.

After completing the second plasma modification process, the processed wafer (W) is carried out of plasma modifying apparatus 100.

In the present embodiment, the film forming process of the silicon oxide by the CVD method and the two-step modification process for the silicon oxide film may be performed continuously under a vacuum state using substrate system 200 (see FIG. 7).

### [Action]

As described above, when generating plasma of the processing gas containing oxygen using microwave excitation plasma modifying apparatus 100, active species in plasma are changed by the processing pressure. That is, O₂⁺ ions or O(¹D₂) radicals in plasma are reduced as active species and O(³Pⱼ) radicals become predominant instead. O(³Pⱼ) radicals have a property to transmit the silicon oxide film (see FIG. 6). For this reason, a radical oxidization proceeds in the interface between the silicon oxide film and the underling silicon layer in the high pressure condition so that the total film thickness of the silicon oxide film increases. Such film increasing action is even more intensified by including hydrogen in the processing gas.

In the plasma modifying method of the present embodiment, based on understating that the active species in plasma changes depending on the processing pressure, the underling silicon of the silicon oxide film is oxidized in the first plasma modification process by selecting the high pressure condition (within a range of above 333 Pa, e.g., 333 Pa to 1333 Pa) where O(³Pⱼ) radicals become predominant as active species. As a result, the thickness of the silicon oxide film is substantially increased. Then, in the second plasma modification process, the silicon oxide film with the increased thickness is modified by selecting the lower pressure condition (below 267 Pa) where the O₂⁺ ions or O(¹D₂) radicals become predominant as active species. Such two-step plasma modification process makes it possible to form a silicon oxide film having a desirable thickness, a higher density, and fewer impurities. And, by proceeding the oxidization in the interface between the silicon oxide film and the underling silicon in the first plasma modification process, the shape of the underling silicon can be changed and a round shape can be introduced into an acute angle part such as the corner portion.

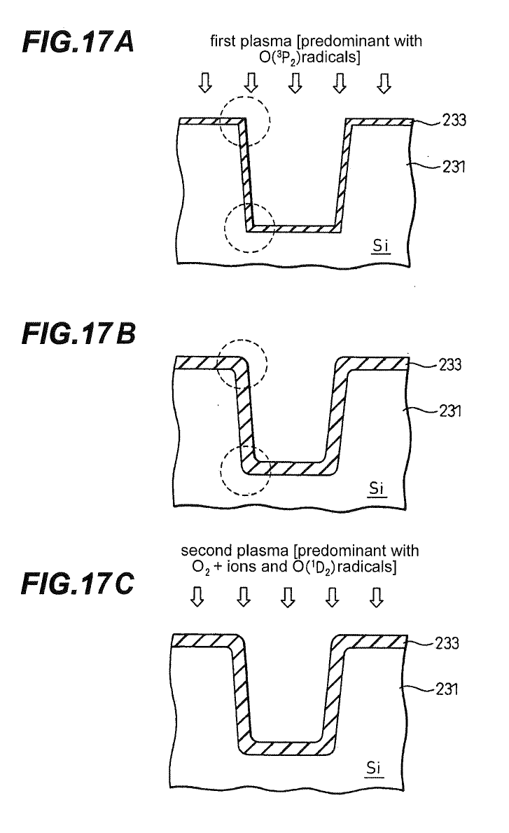

Next, experimental data on which the present invention is based will be explained. As shown in FIG. 17A, a silicon oxide film 233 has been formed with the CVD method on a silicon substrate 231 having a concave/convex shape. The first plasma modification process has been performed for silicon oxide film 233 under the high pressure condition (see the condition 4 of the first embodiment). By the first plasma modification process where O(³Pⱼ) radicals which are easy to penetrate into the inside of silicon oxide film 233 become predominant, the thickness of the silicon oxide film increased as shown in FIG. 17B by oxidizing the silicon in the interface between silicon oxide film 233 and the underling silicon. Subsequently, the second plasma modification process has been performed for silicon oxide film 233 under the low pressure condition (see the condition 1 of the first embodiment). By the second plasma modification process where O₂⁺ ions and O(¹D₂) radicals become predominant, the quality of increased silicon oxide film 233 has been modified as shown in FIG. 17C.

By performing the first plasma modification process under the high pressure condition, the corner part (shoulder part) of the concave/convex shape, which became an acute angle because the silicon oxide film has been formed to be thin with the CVD method as a deposition method, has been increased in thickness so that the thickness of the corner part became equivalent to the other parts (top, bottom or side wall of the concave/convex shape), and thereby the shape of the corner part could be manufactured to be round. And, after changing the shape of the corner part (shoulder part) by the first plasma modification process, the second plasma modification process under the low pressure condition has been performed. As a result, the inside of the silicon oxide film has been modified to be dense and have fewer impurities thereby forming a high quality silicon oxide film.

As described above, with the two-step plasma modification process of the present embodiment, it is possible to control not only the modification effect of the silicon oxide film but also control the shape by increasing the thickness of the silicon oxide film. For this reason, it is preferably applicable to applications which need to form a dense and high quality silicon film, for example, on the surface of the silicon having a concave/convex shape. As examples of such applications, the plasma modification process of the present embodiment may be applied as a post-process after forming the silicon oxide film with the CVD method as a liner on the inner surface of trench in a device isolation technique such as in the STI (Shallow Trench Isolation).

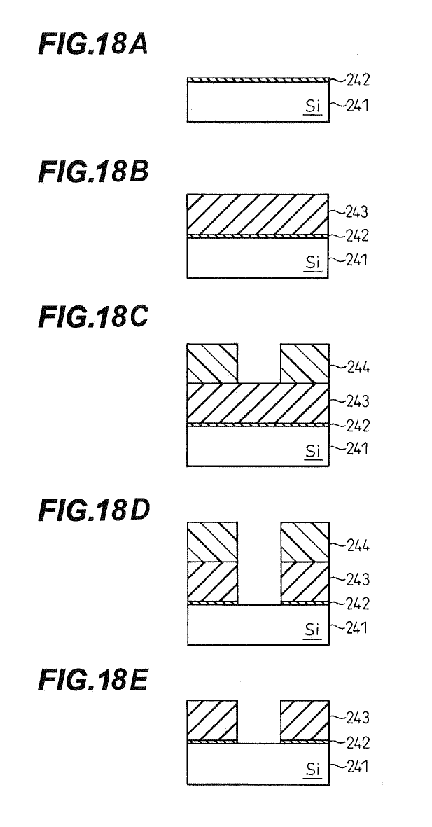

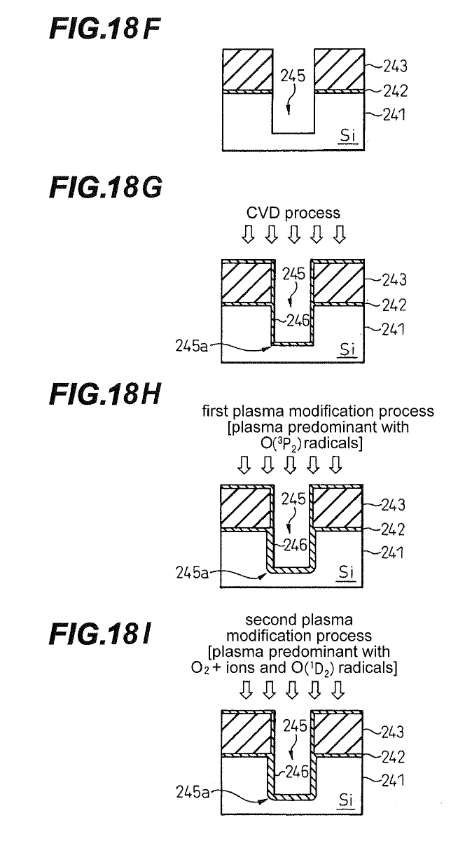

An example of applying the plasma modifying method of the present embodiment to the modification and the shape control of the silicon oxide film inside the trench in the STI is shown in FIG. 18. FIGS. 18A through 18I show the process flow from the formation of the trench in the STI to the plasma modification process performed thereafter.

As shown in FIG. 18A, at first, a silicon oxide film 242 such as SiO₂ is formed on a silicon substrate 241 with, for example, a thermal oxidization method. Next, as shown in FIG. 18B, a silicon nitride film 243 such as Si₃N₄ is formed on silicon oxide film 242 with, for example, CVD (Chemical Vapor Deposition). Further, as shown in FIG. 18C, after coating photo-resist on silicon nitride film 243, a resist layer 244 is formed by a patterning of the photolithography technique.

Next, silicon nitride film 243 and silicon oxide film 242 are selectively etched with an etching gas such as halogen-type using resist layer 244 as an etching mask. Silicon substrate 241 is then exposed corresponding to the pattern of resist layer 244. Then, a mask pattern for trench is formed by silicon nitride film 243 (FIG. 18D). Next, as shown in FIG. 18E, the so-called aching process is carried out to remove resist layer 244, by the oxygen-containing plasma generated using a processing gas including oxygen etc.

Next, as shown in FIG. 18F, trench 245 is formed by selectively etching silicon substrate 241 using silicon nitride film 243 and silicon oxide film 242 as a mask. The etching may be carried out using an etching gas such as, for example, halogen (Cl₂, HBr, SF₆, CF₄), halogen compound, or O₂.

Next, as shown in FIG. 18G a silicon oxide film 246 is formed with the CVD method on the inner surface of trench 245 of the wafer (W) after the etching. Since silicon oxide film 246 is deposited only on the inner surface of trench 245 in this stage, the acute angle shape made by the etching is remained on corner part 245a of trench 245.

Next, in FIG. 18H, the first plasma modification process is performed for silicon oxide film 246 formed on the inner surface of trench 245 under the high pressure condition of above 333 Pa where O(³Pⱼ) radicals become predominant as active species. By performing the first plasma modification process, the silicon oxidization of silicon substrate 241 is progressed on the interface with silicon oxide film 246 so that the thickness of silicon oxide film 246 increases and corner part 245a is manufactured to be round.

Next, as shown in FIG. 18I, the second plasma modification process is performed for silicon oxide film 246 formed on the inner surface of trench 245 under the low pressure condition of below 267 Pa where O₂⁺ ions and O(¹D₂) radicals become predominant as active species. By performing the second plasma modification process, the quality of silicon oxide film 245 is improved to be dense and have fewer impurities.

If corner part 245a of trench 245 for embedding the device isolation layer in the STI has an acute angle shape, the leakage current can readily be generated from that part. As a result, the power saving of the device may be difficult and the reliability of the device may be decreased. Thus, it is important that corner part 245a of trench 245 should be a round shape by making the thickness of silicon oxide film 246 to be thicker thereat. And, by performing the second plasma modification process, a leakage current is suppressed so that the reliability of the device can be increased even higher, by improving the quality of silicon oxide film 246 to be dense and have fewer impurities.

Further, in the present embodiment, it is possible to continuously perform the two-step of the first plasma modification process and the second plasma modification process in the same chamber of plasma processing system 100 while maintaining vacuum condition. The first plasma modification process and the second plasma modification process may be performed on separate chambers.

After modifying silicon oxide film 246 with the plasma modifying method of the present embodiment, according to the order of the device isolation region fabrication by the STI, the silicon oxide film such as SiO₂ is embedded inside trench 245 with, for example, the CVD method and then polished for planarization by a Chemical Mechanical Polishing (CMP) using silicon nitride film 243 as a stopper layer. After planarization, silicon nitride film 243 and the upper part of the embedded insulating film are removed by an etching or the CMP, thereby forming the device isolation structure.

The plasma modifying method of the present embodiment is not limited to modification process of silicon oxide film 246 inside trench 245 of the STI and can be preferably used to improve the quality of silicon oxide film 246 formed on the silicon surface with a concave/convex shape. For example, in the manufacturing process of the 3-dimensional structures such as pin structure, groove-shape gate structure, double gate structure and so forth, the plasma modifying method of the present embodiment is applicable to the modification of the silicon oxide film as a gate insulating film formed on the silicon surface having a 3-dimensional shape of a concave/convex shape.

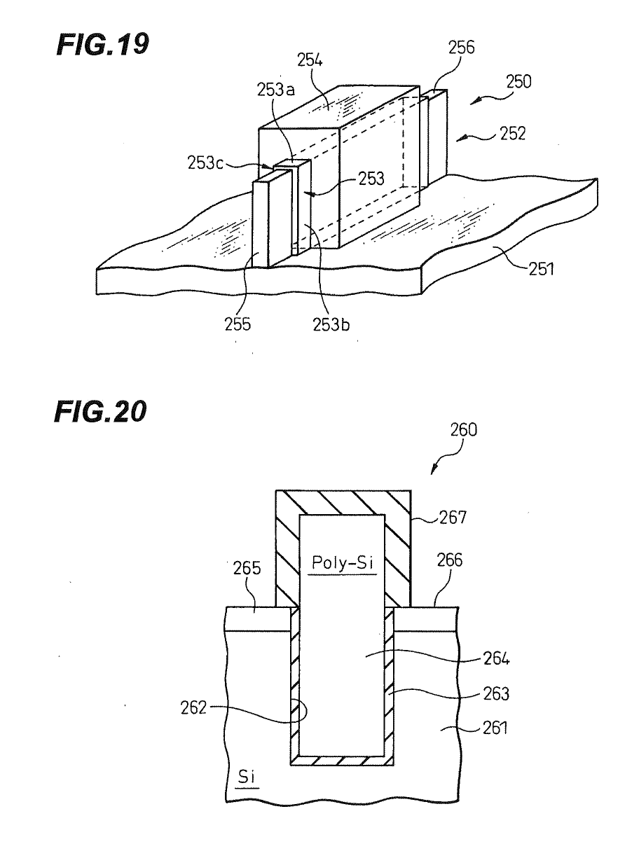

FIG. 19 shows mimetically an exemplary schematic constitution of the MOSFET (Metal Oxide Semiconductor Field Effect Transistor) with the pin structure as an example of a 3-dimensional structure device. MOSFET 250 of the pin structure is provided with a silicon wall 252 of a pin type or a convex type formed on an underlying film 251 such as SiO₂ film. A gate insulating film 253 is formed so as to cover a portion of silicon wall 252, and the 3-dimensional structure with a gate electrode 254 formed therein is prepared by interposing gate insulating film 253. Gate insulating film 253 formed on the surface of silicon wall 252 is covered with gate electrode 245 on three sides of a top part 253a and both sides of wall parts 253b, 253c, thereby forming a transistor of three-gate structure. Since the MOSFET channel can be controlled by three gates, the three-gate structure is superior to a conventional plane type MOSFET that controls the channel region with only one gate in restraining a short channel effect so that it is possible to respond to the miniaturization and high-integration after 32 nm node.

Next, FIG. 20 mimetically illustrates a transistor having a groove-shaped gate as a different example of a 3-dimensional device. Transistor 260 having the groove-shaped gate is formed by embedding gate insulator 263 inside a groove-shaped convex portion 262 according to the method of the present invention, and, for example, the bottom portion of gate electrode 264 made of poly-silicon is embedded. A laminated source 265 and a drain 266 are formed in both sides of convex portion 262, and the transistor is constituted by flowing current between the source and the drain. The upper portion of gate electrode 264 is treated with a surface nitrification (not shown), and an insulating layer 267 such as SiO2 is formed on top of the gate electrode by, for example, the CVD method and the plasma CVD method. In transistor 260 having the groove-shaped gate, since the current flows along the groove (convex portion 262), an effective current path can possibly be longer while the size of the plane gate electrode is limited to be shorter. Accordingly, the short-channel effect is improved thereby complying with the miniaturization and high-integration of the semiconductor devices.

In order to manufacture the 3-dimensional structure device as shown in FIG. 19, convex type silicon wall 252 is formed on underlying film 251 such as SiO₂ film and gate insulating film 253 is formed as silicon oxide film on the surface of silicon wall 252 using, for example, the CVD method.

Further, in order to manufacture the 3-dimensional structure device as shown in FIG. 20, a convex portion 262 of the groove shape (it may be a hole shape) is formed on Si substrate 261 by, for example, a plasma etching and gate insulating film 263 is formed as a silicon oxide film on the surface of convex portion 262 with, for example, the CVD method.

In the 3-dimensional structure device as described above, the leakage current can easily be generated from the corner portion since the thickness of the silicon oxide film tends to be thinner at the corner portion having a concave/convex shape. Accordingly, in the device fabrication process of the 3-dimensional structured device, the shape of the corner portion can be changed by increasing the thickness of silicon oxide layer (gate insulating layer 253, gate insulator 263) formed on the concave/convex shape, and the quality of the film can be improved to be dense and have fewer impurities. As a result, accordingly, low power consumption and reliability improvement can be achieved by reducing the leakage current in the 3-dimensional structure device.

The plasma modifying method of the present embodiment, though not shown, can be used for the purpose of, for example, modification process of the film quality of a side wall spacer in a transistor, as for applications besides the above.

The other constitution, operation, and effect of the present embodiment are the same as the first and the second embodiments.

Though the embodiments of the present inventions are described above, the present invention is not limited to the above embodiments and various modifications can be made thereto. For example, although the silicon oxide film (SiO2 layer) formed by a thermal CVD method is used as a subject to the plasma modification process in the above embodiments, modification process silicon oxide film formed with other methods, such as a plasma CVD method, a reduced pressure CVD method, an atmospheric CVD method, an ALD (Atomic Layer Deposition) method, a MLD (Molecular Layer Deposition) method, a SOG (Spin On Glass) method may be a subject to the plasma modification process. In this case, if the quality of the silicon oxide film is not that higher (e.g., the film quality is more coarse), the higher modification effect may be obtained.

Additionally, the insulating film that can be a subject to the plasma modification process is not limited to the silicon oxide film but the plasma modification process may be applied to a high-dielectric metal oxide film (high-k layer) including metal oxide such as zirconium (Zr), tantalum, titan, barium, strontium, aluminum, hafnium, and the like.

What is claimed is:

1. A method for modifying an insulating film formed on a substrate comprising:
introducing a processing gas containing oxygen and a noble gas into a processing chamber;
introducing a microwave into the processing chamber using a plane antenna having a plurality of holes; and
generating plasma in the processing chamber with a plasma generating condition where O₂⁺ ions and O(¹D₂) radicals become predominant as active species in plasma thereby modifying the insulating film,
wherein the plasma generating condition includes a process pressure which is within a range of 133 Pa to 267 Pa, a flow rate ratio of the oxygen over a total flow of the processing gas which is within a range of 0.1 to 0.23, and a processing temperature which is within a range of 200° C. to 600° C.

2. The method of claim 1, wherein the insulating film is a silicon oxide film formed with a plasma CVD or a thermal CVD.

3. A method for modifying an insulating film formed on a silicon layer that forms a groove of a concave/convex shape comprising:
a first plasma modification process including:
introducing a processing gas containing oxygen and a noble gas into a processing chamber;
introducing a microwave into the processing chamber using a plane antenna having a plurality of holes;
generating a first plasma with a pressure condition within a range of 333 Pa to 1333 Pa thereby oxidizing the silicon layer at an interface between the silicon layer and the insulating film and introducing a round shape into a corner part of the concave/convex shape with the first plasma; and
a second plasma modification process including:
introducing a processing gas containing oxygen and a noble gas into the processing chamber;
introducing a microwave into the processing chamber using the plane antenna;
generating a second plasma where O₂⁺ ions and O(¹D₂) radicals become predominant as active species in plasma with a pressure condition within a range of 6.7 Pa to 267 Pa thereby modifying the insulating film to be dense with the second plasma,
wherein a processing temperature of both the first and second plasma modification processes is within a range of 200° C. to 600° C.

4. The method of claim 3, wherein, in the second plasma modification process, the pressure condition is within a range of 133 Pa to 267 Pa and a flow rate ratio of the oxygen over a total flow of the processing gas is within a range of 0.1 to 0.23.

5. The method of claim 3, wherein the processing pressure for the second plasma generating is within a range of 6.7 Pa to 67 Pa.

6. The method of claim 3, wherein a flow rate ratio of the oxygen over a total flow of the processing gas for the first plasma modification process is within a range of 0.1 to 0.5.

7. The method of claim 6, wherein a flow rate ratio of the hydrogen over a total flow of the processing gas for the first plasma modification process is within a range of 0.01 to 0.2.

8. The method of claim 3, wherein a flow rate ratio of the oxygen over a total flow of the processing gas for the second plasma modification process is within a range of 0.001 to 0.3.

9. The method of claim 3, wherein the insulating film is a silicon oxide film deposited with a CVD method using dichlorosilane (SiH₂Cl₂) and N₂O as raw materials.

10. The method of claim 3, wherein the silicon layer has a 3-dimensional structure and the insulating film is formed along a trench surface of the concave/convex shape.

11. A plasma processing apparatus comprising:
a processing chamber configured to process a substrate with plasma;
a plane antenna having a plurality of holes configured to introduce microwaves into the processing chamber;
a gas supply unit configured to supply a raw gas into the processing chamber;
an exhaust unit configured to depressurize and exhaust inside the processing chamber;
a temperature control unit configured to control the temperature of the substrate; and
a control unit configured to control a plasma modifying method to be executed in the processing chamber,
wherein the plasma modifying method comprises:
introducing a processing gas containing oxygen and a noble gas into the processing chamber;
introducing a microwave into the processing chamber using the plane antenna having the plurality of holes; and
generating plasma in the processing chamber with a plasma generating condition where O₂⁺ ions and O(¹D₂) radicals become predominant as active species in plasma thereby modifying an insulating film formed on the substrate,
wherein the plasma generating condition includes a process pressure which is within a range of 133 Pa to 267 Pa, a flow rate ratio of the oxygen over a total flow of the processing gas which is within a range of 0.1 to 0.23, and a processing temperature which is within a range of 200° C. to 600° C.

12. A plasma processing apparatus comprising:
a processing chamber configured to process a substrate using plasma;
a plane antenna having a plurality of holes configured to introduce a microwave into the processing chamber;
a gas supply unit configured to supply a raw gas in the processing chamber;
an exhaust unit configured to depressurize and exhaust inside the processing chamber;
a temperature control unit configured to control the temperature of the substrate; and
a control unit configured to control a plasma modifying method to be executed in the processing chamber,
wherein the plasma modifying method comprises:
introducing a processing gas containing oxygen and a noble gas into the processing chamber;
introducing a microwave into the processing chamber using the plane antenna having the plurality of holes;
generating a first plasma with a pressure condition within a range of 333 Pa to 1333 Pa thereby oxidizing a silicon layer forming a groove of a concave/convex shape that is underlying layer of an insulating film formed on the substrate and introducing a round shape into a corner part of the concave/convex shape the with the first plasma; and
generating a second plasma where O₂⁺ ions and O(¹D₂) radicals become predominant as active species in plasma with a pressure condition within a range of 6.7 Pa to 267 Pa thereby modifying the insulating film to be dense with the second plasma.
